(19) United States
(12) Patent Application Publication
(10) Pub. No.: US 2008/0133999 A1
(43) Pub. Date: Jun. 5, 2008

(54) Error correcting apparatus and error correcting method

(75) Inventors: Yosuke Kondo, Ome-shi (JP); Kenji Yoshida, Akishima-shi (JP)

Correspondence Address: PILLSBURY WINTHROP SHAW PITTMAN, LLP, P.O. BOX 10500, MCLEAN, VA, 22102, US

(73) Assignee: KABUSHIKI KAISHA TOSHIBA, Tokyo (JP)

(21) Appl. No.: 11/978,631

(22) Filed: Oct. 30, 2007

(30) Foreign Application Priority Data
Nov. 30, 2006 (JP) 2006-325023

(51) Int. Cl. H03M 13/05; G06F 11/10

(52) U.S. Cl. 714/755; 714/E11.032

(57) ABSTRACT

According one embodiment, after receiving, as a received bit sequence, an information bit sequence which has been encoded for an error correction in the form of connecting an error correcting code to the outside of an LDPC code, the received bit sequence is subjected to the LDPC decoding, and then subjected to an error correction corresponding to the error correcting code. When the error correction corresponding to the error correcting code is impossible, a bit with low reliability is detected from the received bit sequence subjected to the LDPC decoding, and the bit is inverted, and then the received bit sequence with the inverted bit is subjected to an error correction corresponding to the error correcting code.

### CROSS-REFERENCE TO RELATED APPLICATIONS

This application is based upon and claims the benefit of priority from Japanese Patent Application No. 2006-325023, filed Nov. 30, 2006, the entire contents of which are incorporated herein by reference.

### BACKGROUND

1. Field

One embodiment of the invention relates to improvements in an error correcting apparatus and an error correcting method for error correcting an information bit sequence encoded for an error correction.

2. Description of the Related Art

As is well known, when an information bit sequence is recorded in or reproduced from an information recording medium such as a hard disk or an optical disk, the information bit sequence is recorded after being encoded for an error correction in the case of recording, while the information bit sequence read from the information recording medium is error-corrected on the basis of an error correcting code to restore the original information bit sequence in the case of reproduction.

Meanwhile, a low density parity check (LDPC) code is currently being keenly researched, and is attracting attention as next-generation error correcting encoding for an information bit sequence to be recorded. This LDPC code causes fewer error floors than a turbo code, but still needs measures for the error floors when introduced into, for example, a hard disk drive (HDD) requiring high reliability.

In reducing or compensating for the error floors, connecting an error correcting code such as a Reed-Solomon (RS) code or BCH code to the outside of the LDPC code is considered to be effective. However, in this method, the encoding rate of each code has to be higher to maintain a constant value of format efficiency than when the LDPC code and the error correcting code are independently used, thus the error correcting capabilities of both the LDPC code and the error correcting code cannot necessarily be sufficiently demonstrated.

Jpn. Pat. Appln. KOKAI Publication No. 2006-109019 has disclosed saving positional information for output soft data from a Viterbi decoder when the value of the output soft data is equal to or more than a threshold value, and inverting a bit corresponding to the positional information in which a decoding block of the output soft data is saved, and then again making a cyclic redundancy check (CRC) decision when the result of the hard decision of the output soft data is regarded as erroneous by the CRC.

### BRIEF DESCRIPTION OF THE SEVERAL VIEWS OF THE DRAWINGS

A general architecture that implements the various feature of the invention will now be described with reference to the drawings. The drawings and the associated descriptions are provided to illustrate embodiments of the invention and not to limit the scope of the invention.

FIG. 1 is a block configuration diagram showing one embodiment of this invention for explaining the outline of an HDD;

FIG. 2 is a block configuration diagram shown to explain one example of a decoding unit incorporated in the HDD in this embodiment;

FIG. 3 is a flowchart shown to explain one example of the whole processing operation of the decoding unit in this embodiment;

FIG. 4 is a flowchart shown to explain one example of the processing operation of essential parts of the decoding unit in this embodiment; and

FIG. 5 is a flowchart shown to explain another example of the processing operation of the essential parts of the decoding unit in this embodiment.

### DETAILED DESCRIPTION

Various embodiments according to the invention will be described hereinafter with reference to the accompanying drawings. In general, according to one embodiment of the invention, after receiving, as a received bit sequence, an information bit sequence which has been encoded for an error correction in the form of connecting an error correcting code to the outside of an LDPC code, the received bit sequence is subjected to the LDPC decoding, and then subjected to an error correction corresponding to the error correcting code. When the error correction corresponding to the error correcting code is impossible, a bit with low reliability is detected from the received bit sequence subjected to the LDPC decoding, and the bit is inverted, and then the received bit sequence with the inverted bit is subjected to an error correction corresponding to the error correcting code.

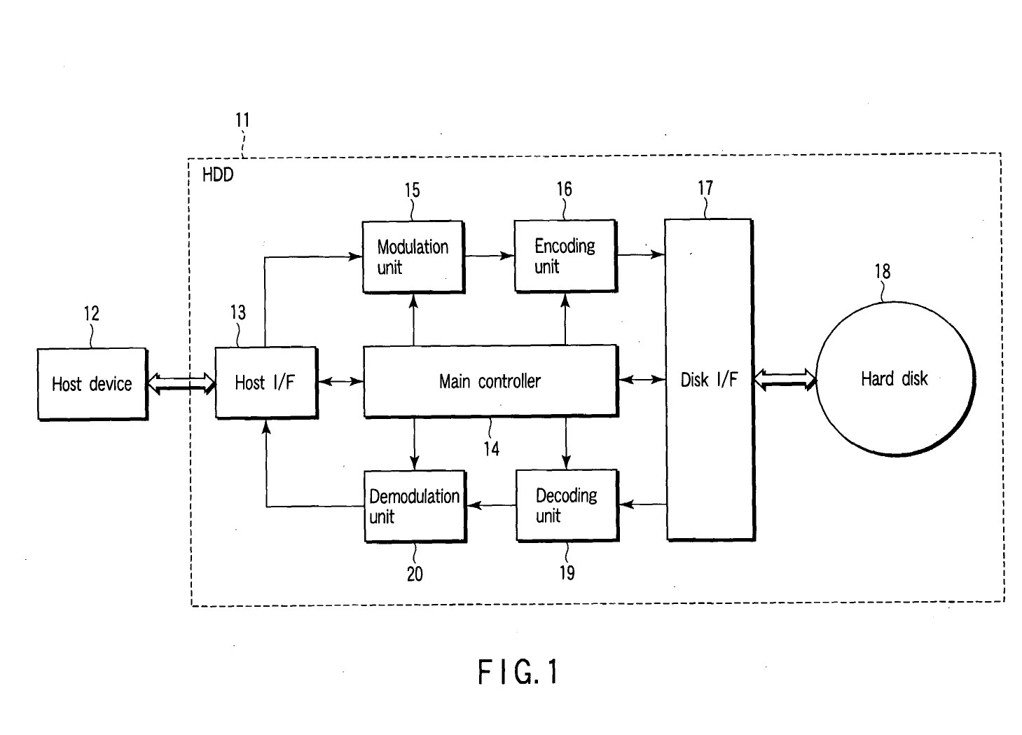

FIG. 1 schematically shows the outline of an HDD 11, which is an information recording/reproducing apparatus described in this embodiment. That is, this HDD 11 comprises a host interface (I/F) 13 for transmitting/receiving information to/from an external host device 12.

Here, the host device 12 is, for example, a personal computer (PC). This host device 12 uses the HDD 11 to write and read information, for example, when executing predetermined application software, and can also use the HDD 11 as a destination to save information finally obtained.

In this case, the host device 12 generates a command for requesting the HDD 11 to write or read the information. This command is supplied to a main controller 14 via the host I/F 13. This main controller 14 has a central processing unit (CPU) therein, and has overall control of various operations performed by the HDD 11.

For example, when a write request command is supplied from the host device 12, this write request command is supplied to the main controller 14 via the host I/F 13 and analyzed therein. Thus, the main controller 14 drives a modulation unit 15 and an encoding unit 16, and controls a hard disk 18 via a disk I/F 17 to bring the hard disk 18 into a write state.

Furthermore, an information bit sequence to be written is supplied to the modulation unit 15 via the host I/F 13. This modulation unit 15 subjects the input information bit sequence to modulation (e.g., modulation to prevent zeros from exceeding a given length) such as run-length modulation in a form corresponding to a request from a recording/reproduction system in the HDD 11.

The information bit sequence modulated by this modulation unit 15 is supplied to the encoding unit 16. This encoding unit 16 subjects the input information bit sequence to error correcting encoding in the form of connecting an error correcting code such as an RS code or a BCH code to the outside of an LDPC code.

Then, the information bit sequence subjected to the error correcting encoding performed by the encoding unit 16 is written into the hard disk 18 via the disk I/F 17, whereby processing for writing the information bit sequence into the hard disk 18 based on the write request from the host device 12 is executed.

Furthermore, when a read request command is supplied from the host device 12, the read request command is supplied to the main controller 14 via the host I/F 13 and analyzed therein. Thus, the main controller 14 drives a decoding unit 19 and a demodulation unit 20, and controls the hard disk 18 via the disk I/F 17 to bring the hard disk 18 into a read state.

Then, the information bit sequence which has been read from the hard disk 18 and encoded for an error correction is supplied to the decoding unit 19 via the disk I/F 17. This decoding unit 19, which will be described later in detail, subjects the input received bit sequence to error corrections corresponding to the LDPC code and the error correcting code.

The received bit sequence subjected to the error correction by the decoding unit 19 is supplied to the demodulation unit 20. This demodulation unit 20 demodulates the modulation such as the run-length modulation subjected to the input received bit sequence, and restores the original information bit sequence.

Then, the received bit sequence demodulated by the demodulation unit 20 is output to the host device 12 via the host I/F 13, whereby processing for reading the information bit sequence from the hard disk 18 based on the read request from the host device 12 is executed.

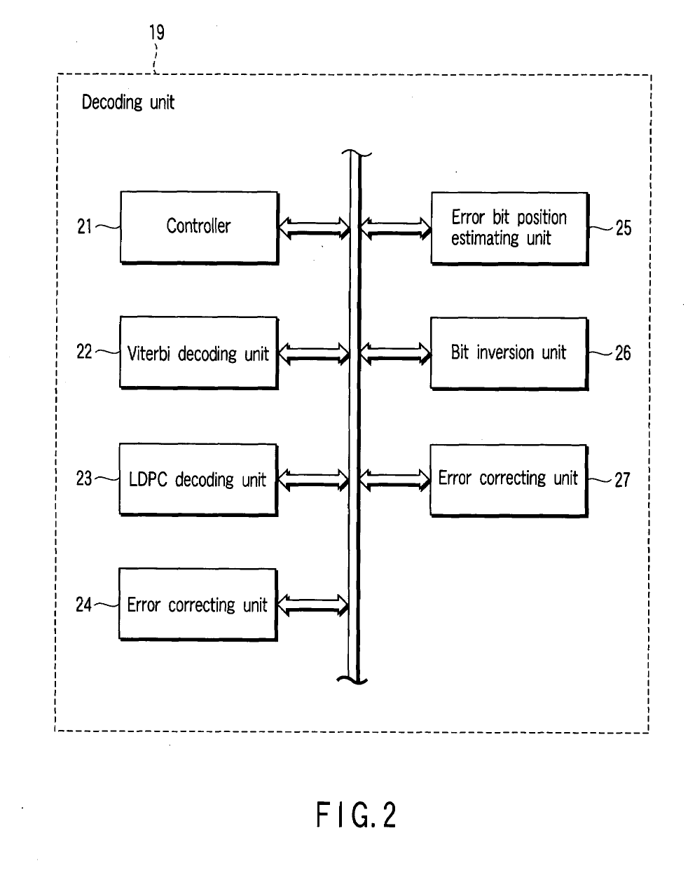

FIG. 2 shows one example of the decoding unit 19. That is, the decoding unit 19 comprises a controller 21 which is capable of transmitting/receiving data to/from the main controller 14 and which has, under the control of the main controller 14, overall control of various operations performed by the decoding unit 19.

The decoding unit 19 further comprises a Viterbi decoding unit 22. This Viterbi decoding unit 22 subjects the input received bit sequence to soft decision Viterbi decoding based on SOVA or a max-log-map algorithm, and outputs a probability value indicating, for example, the “0” likelihood or “1” likelihood of each bit.

Furthermore, the decoding unit 19 comprises an LDPC decoding unit 23. This LDPC decoding unit 23 subjects the input received bit sequence to LDPC decoding in units of the code word of an LDPC code. The LDPC decoding unit 23 receives a probability value output from the Viterbi decoding unit 22, calculates the likelihood of each bit, and outputs the result of its hard decision to an error correcting unit 24.

This error correcting unit 24 subjects the hard-decided received bit sequence to an error correction based on an error correcting code such as an RS code or a BCH code. When a correction can be made as a result of the error correction, the received bit sequence after the correction is supplied as it is to the demodulation unit 20 as an output of the decoding unit 19.

When the error correction cannot be achieved by the error correcting unit 24, that is, when the number of the errors present exceeds the error correcting capability of the error correcting unit 24, the following processing is performed. That is, the decoding unit 19 comprises an error bit position estimating unit 25.

This error bit position estimating unit 25 extracts candidates of bits with low reliability from the bit sequence output from the LDPC decoding unit 23 or places the bits in ascending order of reliability on the basis of parity error information and likelihood values obtained in the decoding process by the LDPC decoding unit 23, and outputs the result to a bit inversion unit 26.

This bit inversion unit 26 inverts the bits output from the LDPC decoding unit 23 on the basis of the candidates of the bits with low reliability and the order output from the error bit position estimating unit 25, and outputs the result to an error correcting unit 27. This error correcting unit 27 subjects the input received bit sequence to an error correction based on an error correcting code such as an RS code or a BCH code. When a correction can be made as a result of the error correction, the received bit sequence after the correction is supplied to the demodulation unit 20 as an output of the decoding unit 19.

When the error correction cannot be achieved by the error correcting unit 27, the following processing is repeated: the bit output from the LDPC decoding unit 23 is inverted by the bit inversion unit 26 on the basis of the next candidate and the order designated by the error bit position estimating unit 25, and the result is output to the error correcting unit 27, such that an error is corrected.

Here, means of estimating an error bit position performed by the error bit position estimating unit 25 is explained. That is, when a parity equation is not satisfied in any one of the rows in a check matrix of the LDPC code in the decoding process performed by the LDPC decoding unit 23, there has to be an erroneously hard-decided bit in that row. If, for example, this bit has a likelihood lower than the likelihood of other bits, it is possible to find its position.

That is, the error bit position is identified on the basis of the parity error information or the likelihood values obtained in the decoding process by the LDPC decoding unit 23 on the condition that an erroneously decided bit has a low likelihood, and the bit is then inverted, such that an error is corrected and the error correction in the error correcting unit 27 is possible. This can improve an error correcting rate while maintaining the resistance to error floors.

For example, when the bit sequence output from the LDPC decoding unit 23 contains the number of errors larger by one than the number of errors that can be corrected in the error correcting unit 27, a candidate of the error bit position is extracted, and the bit of the extracted bit position is inverted, so that if the error of the one bit is corrected, the number of errors can fall within the error correcting capacity of the error correcting unit 27, and it is possible to make good use of the capacity of the error correction based on the error correcting code.

Moreover, in the above-mentioned check matrix, the bits of the rows having the parity errors are inverted in accordance with the order designated by the error bit position estimating unit 25 until the error correction in the error correcting unit 27 is possible, such that the error correcting rate can also be improved.

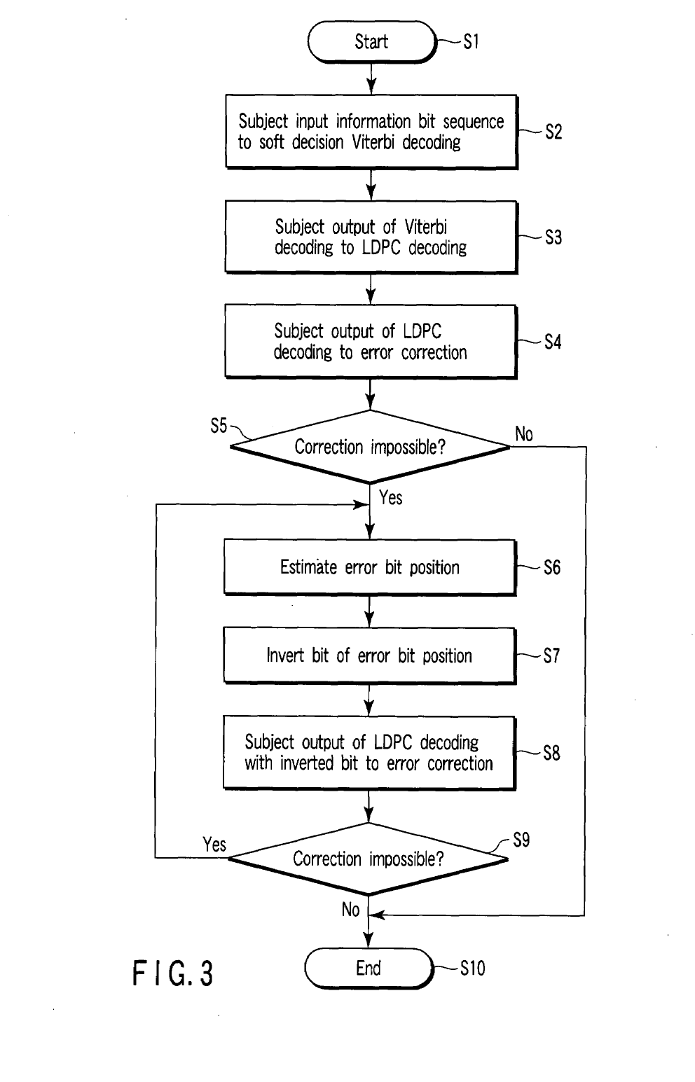

FIG. 3 shows a flowchart summing up the error correcting operation in the decoding unit 19. That is, when the processing is started (step S1), the decoding unit 19 subjects the received bit sequence input by the Viterbi decoding unit 22 to the soft decision Viterbi decoding (in step S2).

Then, the decoding unit 19 causes the LDPC decoding unit 23 to subject the output of the Viterbi decoding unit 22 to the LDPC decoding in step S3, and causes the error correcting unit 24 to subject the bit sequence output from the LDPC decoding unit 23 to an error correction in step S4, and then judges in step S5 whether the error correction performed by the error correcting unit is impossible.

Here, when it is judged that the error correction is not impossible (NO), the decoding unit 19 supplies the received bit sequence error-corrected in the error correcting unit 24 to the demodulation unit 20, such that the processing is finished (step S10).

When it is judged in step S5 that the error correction is impossible (YES), the decoding unit 19 causes the error bit position estimating unit 25 to estimate the error bit position of the bit sequence output from the LDPC decoding unit 23 in step S6, and causes the bit inversion unit 26 to invert the bit designated as an error bit position in the bit sequence output from the LDPC decoding unit 23 in step S7.

Then, the decoding unit 19 causes the error correcting unit 27 to subject the bit sequence with the inverted bit output from the LDPC decoding unit 23 to an error correction in step S8, and then judges in step S9 whether the error correction performed by the error correcting unit 24 is impossible.

Here, when it is judged that the error correction is not impossible (NO), the decoding unit 19 supplies the received bit sequence error-corrected in the error correcting unit 27 to the demodulation unit 20, such that the processing is finished (step S10).

When it is judged in step S9 that the error correction is impossible (YES), the decoding unit 19 is returned to the processing in step S6, and causes the error bit position estimating unit 25 to estimate the next candidate of the error bit position, and is then shifted to the processing in step S7.

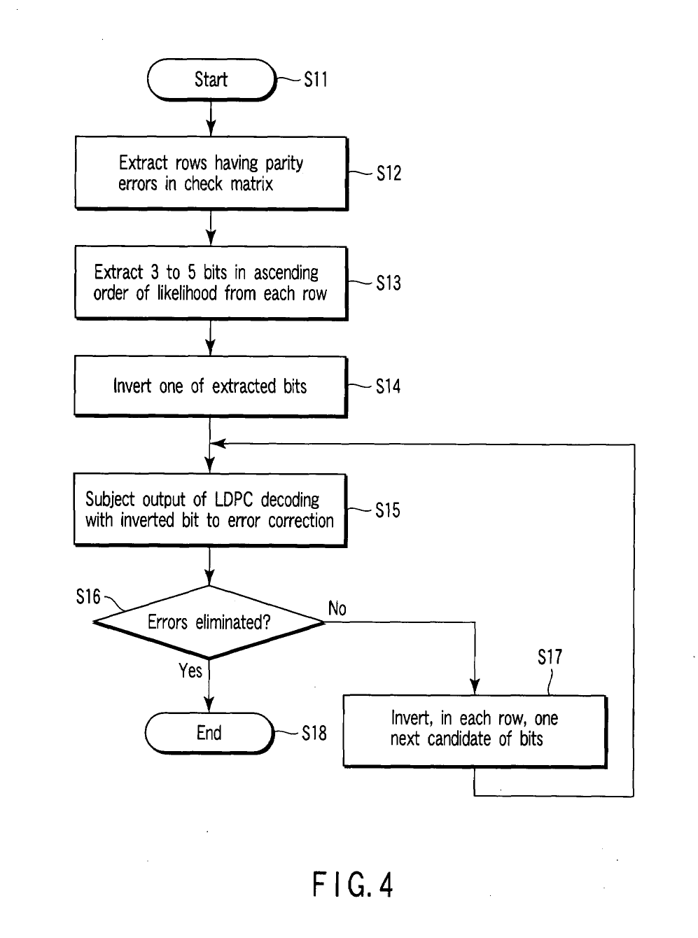

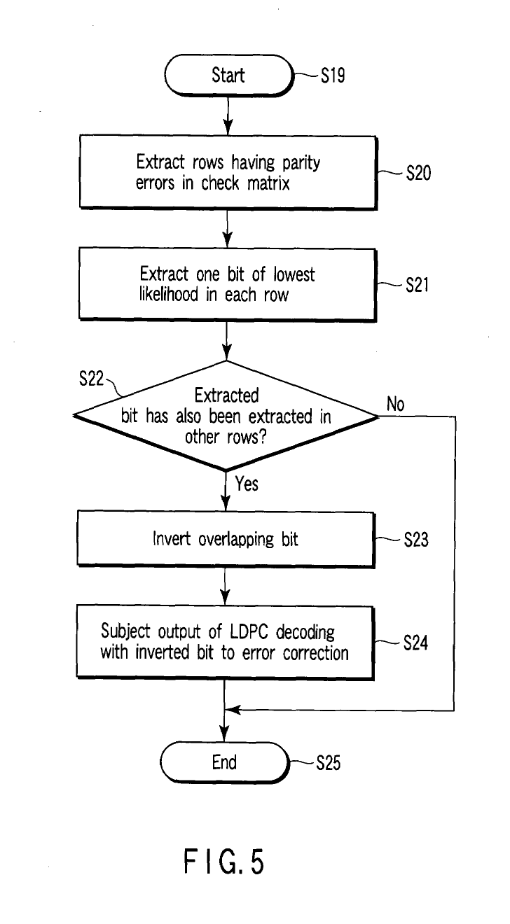

FIGS. 4 and 5 show flowcharts summing up a specific operation example when an error correction is made by inverting the bit designated by the error bit position estimated in the error bit position estimating unit 25.

First, as shown in FIG. 4, when the processing is started (step S1), the decoding unit 19 causes the error bit position estimating unit 25 to extract rows having parity errors in the check matrix in step S12 and to further extract 3 to 5 bits in ascending order of likelihood from each of the extracted rows in step S13.

Then, the decoding unit 19 causes the bit inversion unit 26 to invert, in each row, one of the bits extracted in the error bit position estimating unit 25 in step S14, and causes the error correcting unit 27 to subject the bit sequence with the inverted bit output from the LDPC decoding unit 23 to an error correction in step S15.

Then, the decoding unit 19 judges in step S16 whether the errors in the received bit sequence have been eliminated. When the decoding unit 19 judges that the errors have not been eliminated (NO), the decoding unit 19 causes the bit inversion unit 26 to invert, in each row, one next candidate of the bits extracted in the error bit position estimating unit 25 in step S17, and is then shifted to the processing in step S15. When the decoding unit 19 judges that the errors in the received bit sequence have been eliminated (YES), the processing is finished (step S18).

Furthermore, as shown in FIG. 5, when the processing is started (step S19), the decoding unit 19 causes the error bit position estimating unit 25 to extract rows having parity errors in the check matrix in step S20 and to further extract one bit of the lowest likelihood from each of the extracted rows in step S21.

Then, the decoding unit 19 judges whether the extracted bit has also been extracted in other rows in step S22. When the decoding unit 19 judges that the extracted bit has not been extracted in other rows (NO), the processing is finished (step S25).

When the decoding unit 19 judges in step S22 that the extracted bit has also been extracted in other rows (YES), the decoding unit 19 causes the bit inversion unit 26 to invert the overlapping bit in step S23, and causes the error correcting unit 27 to subject the bit sequence with the inverted bit output from the LDPC decoding unit 23 to an error correction in step S24, such that the processing is finished (step S25).

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. An error correcting apparatus comprising:
a first processing section configured to subject a received bit sequence to low density parity check (LDPC) decoding after receiving, as the received bit sequence, an information bit sequence which has been encoded for an error correction in the form of connecting an error correcting code to the outside of an LDPC code, and subject the received bit sequence subjected to the LDPC decoding to an error correction corresponding to the error correcting code; and
a second processing section configured to invert a bit with low reliability after detecting the bit from the received bit sequence subjected to the LDPC decoding, and subject the received bit sequence with the inverted bit to an error correction corresponding to the error correcting code when the error correction corresponding to the error correcting code by the first processing section is impossible.

2. An error correcting apparatus according to claim 1, wherein
the second processing section is configured to detect a bit with low reliability from the received bit sequence subjected to the LDPC decoding on the basis of information obtained in the process of the LDPC decoding when the error correction corresponding to the error correcting code performed by the first processing section is impossible.

3. An error correcting apparatus according to claim 2, wherein
the second processing section is configured to
detect a row having an error bit in a check matrix on the basis of parity error information obtained in the process of the LDPC decoding, and
identify a bit with low reliability in the detected row on the basis of information indicating likelihood obtained in the process of the LDPC decoding.

4. An error correcting apparatus according to claim 3, wherein
the second processing section is configured to extract a predetermined number of bits in ascending order of the likelihood from the row detected on the basis of the parity error information, and invert one of the extracted bits to subject the bit to the error correction corresponding to the error correcting code, and when this error correction is impossible, then invert another one of the extracted bits to subject the bit to the error correction corresponding to the error correcting code.

5. An error correcting apparatus according to claim 3, wherein
the second processing section is configured to extract one bit of the lowest likelihood from each of the plurality of rows detected on the basis of the parity error information, and invert the extracted bit when the bit is also extracted in other rows.

6. An error correcting apparatus according to claim 1, wherein
the first processing section includes:
an LDPC decoding unit configured to subject the received bit sequence to the LDPC decoding after receiving, as the received bit sequence, the information bit sequence which has been encoded for an error correction in the form of connecting the error correcting code to the outside of the LDPC code; and
a first error correcting unit configured to subject the received bit sequence subjected to the LDPC decoding in the LDPC decoding unit to the error correction corresponding to the error correcting code, and
the second processing section includes:
a detection unit configured to detect a bit with low reliability from the received bit sequence subjected to the LDPC decoding when the error correction performed by the first error correcting unit is impossible;
an inversion unit configured to invert the bit detected in the detection unit; and
a second error correcting unit configured to subject the received bit sequence containing the bit inverted in the inversion unit to the error correction corresponding to the error correcting code.

7. An information reproducing apparatus comprising:
a receiving unit configured to receive an information bit sequence which has been encoded for an error correction in the form of connecting an error correcting code to the outside of an LDPC code;
an LDPC decoding unit configured to subject the bit sequence received in the receiving unit to the LDPC decoding;
a first error correcting unit configured to subject the received bit sequence subjected to the LDPC decoding in the LDPC decoding unit to the error correction corresponding to the error correcting code;
a detection unit configured to detect a bit with low reliability from the received bit sequence subjected to the LDPC decoding when the error correction performed by the first error correcting unit is impossible;
an inversion unit configured to invert the bit detected in the detection unit;
a second error correcting unit configured to subject the received bit sequence containing the bit inverted in the inversion unit to the error correction corresponding to the error correcting code; and
an output unit configured to subject an output of the first or second error correcting unit to predetermined demodulation processing and output the result to the outside.

8. An error correcting method comprising:
first processing to subject a received bit sequence to LDPC decoding after receiving, as the received bit sequence, an information bit sequence which has been encoded for an error correction in the form of connecting an error correcting code to the outside of an LDPC code, and subject the received bit sequence subjected to the LDPC decoding to an error correction corresponding to the error correcting code; and
second processing to invert a bit with low reliability after detecting the bit from the received bit sequence subjected to the LDPC decoding, and subject the received bit sequence with the inverted bit to an error correction corresponding to the error correcting code when the error correction corresponding to the error correcting code performed by the first processing is impossible.

9. An error correcting method according to claim 8, wherein
the second processing includes:
detecting a row having an error bit in a check matrix on the basis of parity error information obtained in the process of the LDPC decoding; and
identifying a bit with low reliability in the detected row on the basis of information indicating likelihood obtained in the process of the LDPC decoding.

10. An error correcting method according to claim 9, wherein
the second processing includes extracting a predetermined number of bits in ascending order of the likelihood from the row detected on the basis of the parity error information, and inverting one of the extracted bits to subject the bit to the error correction corresponding to the error correcting code, and when this error correction is impossible, then inverting another one of the extracted bits to subject the bit to the error correction corresponding to the error correcting code.

11. An error correcting method according to claim 9, wherein
the second processing includes extracting one bit of the lowest likelihood from each of the plurality of rows detected on the basis of the parity error information, and inverting the extracted bit when the bit is also extracted in other rows.

12. An error correcting method according to claim 8, wherein
the first processing includes:
subjecting the received bit sequence to the LDPC decoding after receiving, as the received bit sequence, the information bit sequence which has been encoded for an error correction in the form of connecting the error correcting code to the outside of the LDPC code; and
subjecting the received bit sequence subjected to the LDPC decoding to the error correction corresponding to the error correcting code, and
the second processing includes:
detecting a bit with low reliability from the received bit sequence subjected to the LDPC decoding when the error correction performed by the first processing is impossible;
inverting the detected bit; and
subjecting the received bit sequence containing the inverted bit to the error correction corresponding to the error correcting code.
